(19) United States
(12) Patent Application Publication
(10) Pub. No.: US 2009/0057909 A1
(43) Pub. Date: Mar. 5, 2009

(54) UNDER BUMP METALLIZATION STRUCTURE HAVING A SEED LAYER FOR ELECTROLESS NICKEL DEPOSITION

(75) Inventor: Thomas Strothmann, Tucson, AZ (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(73) Assignee: FlipChip International, LLC, Phoenix, AZ (US)

(21) Appl. No.: 12/142,415

(22) Filed: Jun. 19, 2008

Related U.S. Application Data
(60) Provisional application No. 60/945,310, filed on Jun. 20, 2007.

(51) Int. Cl. H01L 23/48

(52) U.S. Cl. 257/766

(57) ABSTRACT

Structures and methods for fabrication of an under bump metallization (UBM) structure having a metal seed layer and electroless nickel deposition layer are disclosed involving a UBM structure comprising a semiconductor substrate, at least one final metal layer, a passivation layer, a metal seed layer, and a metallization layer. The at least one final metal layer is formed over at least a portion of the semiconductor substrate. Also, the passivation layer is formed over at least a portion of the semiconductor substrate. In addition, the passivation layer includes a plurality of openings. Additionally, the passivation layer is formed of a non-conductive material. The at least one final metal layer is exposed through the plurality of openings. The metal seed layer is formed over the passivation layer and covers the plurality of openings. The metallization layer is formed over the metal seed layer. The metallization layer is formed from electroless deposition.

### RELATED APPLICATION

This application claims the benefit of and priority to U.S. Provisional Application Ser. No. 60/945,310, filed Jun. 20, 2007, the contents of which are incorporated by reference herein in its entirety.

### BACKGROUND

1. Field

The present disclosure relates to microelectronic semiconductor wafer level chip-scale and flip chip processing. More specifically, fabrication of an under bump metallization structure having a metal seed layer and electroless nickel deposition layer, and associated methods of manufacture are disclosed.

2. General Background

Flip chip technology is an advanced semiconductor technology wherein the chip or die is placed face down and bonded to the substrate with various interconnection materials. In flip chip attachment, solder bumps are deposited on a chip or die, and utilized for electrical interconnections between a chip or an integrated circuit and a substrate.

Wafer level chip-scale packaging and wafer level packaging advance the concept of the flip chip by forming the electrical connections directly on the semiconductor device during fabrication of the semiconductor device. This allows the semiconductor device to be directly mounted to a printed circuit board, thereby eliminating the need for a separate package. The resulting packaged device is similarly sized to the bare semiconductor device.

The under bump metallization (UBM) layer of the flip chip is the support for the entire structure. The UBM is required to serve as a solderable surface, and to provide a barrier layer between the solder and the final metal layer of the pad metallurgy. The UBM must meet several requirements including, but not limited to, providing a strong, stable, low resistance electrical connection to the final metal layer, adhering well to aluminum and the passivation layer to seal the aluminum from the environment, and providing a strong barrier to prevent diffusion of other bump metals.

FIGS. 1A and 1B illustrate a conventional wafer prior to processing. The device comprises a substrate 10, a device final metal 12, and a device passivation layer 14. The substrate 10 may be comprised of materials including, but not limited to, silicon, gallium arsenide, lithium tantalate, silicon germanium, or other suitable wafer substrates utilized in the semiconductor industry. The device final metal 12 is comprised of a metal, typically aluminum, copper or gold, or a composite of these materials.

The device passivation layer 14 typically comprises a silicon nitride, oxidenitride, or the like. The passivation layer is not continuous, but rather has defined openings where there is no passivation material, which are individually referred to as a passivation opening. The passivation opening is normally circular and centered on the device. The passivation opening defines a region in which metal will subsequently be deposited in the wafer level chip-scale or flip chip packaging processing to make a connection and adhere to the device.

FIG. 2A illustrates a top view of a conventional UBM 16 formed by the electroless nickel process, and FIG. 2B illustrates a cross sectional view of a conventional UBM 16 formed by the electroless nickel process. The UBM 16 partially covers the passivation layer 14, adheres to the final metal 12, and typically forms a layer of about 1.0 microns or greater. The upper surface of the UBM 16 provides a site for solder bump placement, and facilitates adherence thereof.

However, there are several disadvantages to the use of electroless nickel to form the UBM. Electroless nickel does not adhere to the passivation layer. In some cases, there is inconsistent deposition of the electroless nickel due to variation in the final metal alloy as well as inconsistent passivation contact resulting in contact openings. This may create problems with the integrity of the electronic devices by not providing a stable, low resistance, electrical contact. Additionally, moisture may form in these contact openings, resulting in areas where the solder bump is not bound properly and, thus, causing problems with the electrical contacts.

Additionally, deposition of electroless nickel on electronic devices that are otherwise unsuitable for the electroless nickel deposition may be difficult. For example, pure aluminum, copper, and gold may not properly adhere to the electroless nickel unless the electroless process chemistry is specifically optimized for each of the individual metals. Other final metal layers may not have the proper electrical conductivity with the electroless nickel to provide a strong electrical connection.

Other conventional flip chip and wafer level chip-scale packaging devices use thin film sputtering for depositing a thin metal layer for use as the UBM. However, these sputtered layers are more expensive, and are not as thick as the electroless nickel layers. As a result, the thermo-mechanical performance of the UBM is not as strong. As markets for bumping products continue to grow, cost and performance pressures are forcing the industry to find better-performing thin film technologies.

### SUMMARY

In one aspect of the present disclosure, there is provided an under bump metallization structure utilizing electroless nickel on a metallic seed layer that provides improved thermo-mechanical ability, consistent deposition, and structural and electrical compatibility with a number of final metal layers.

### DRAWINGS

The accompanying drawings, which are included to provide a further understanding of the disclosed under bump metallization structure having improved metallic properties and drop test performance and are incorporated in and constitute a part of the specification, illustrate exemplary embodiments and, together with the description, serve to explain at least one embodiment thereof, wherein:

FIG. 1A illustrates a top view of a wafer prior to undergoing processing having a passivation opening and a final metal layer.

FIG. 1B illustrates a cross sectional view of a wafer prior to undergoing processing having a passivation opening and a final metal layer.

FIG. 2A illustrates a top view of a wafer having a conventional UBM formed by the electroless nickel process.

FIG. 2B illustrates a cross sectional view of a wafer having a conventional UBM formed by the electroless nickel process.

FIG. 3A illustrates a top view of a wafer having an unpatterned, thin metal seed layer deposited thereon.

FIG. 3B illustrates a cross sectional view of a wafer having an unpatterned, thin metal seed layer deposited thereon.

FIG. 4A illustrates a top view of a patterned photo resist layer placed on the metal seed layer.

FIG. 4B illustrates a cross sectional view of a patterned photo resist layer placed on the metal seed layer.

FIG. 5A illustrates a top view of the metal seed layer after the exposed metal is chemically etched and the photo resist is removed.

FIG. 5B illustrates a cross sectional view of the metal seed layer after the exposed metal is chemically etched and the photo resist is removed.

FIG. 6A illustrates a top view of the finished UBM structure after the electroless nickel is on the patterned seed layer.

FIG. 6B illustrates a top view of the finished UBM structure after the electroless nickel is on the patterned seed layer.

FIG. 7A illustrates a top view of a patterned photo resist layer placed on the metal seed layer for an alternative UBM structure.

FIG. 7B illustrates a cross sectional view of a patterned photo resist layer placed on the metal seed layer for an alternative UBM structure.

FIG. 8A illustrates a top view of the metal seed layer after the exposed metal is chemically etched and the photo resist is removed for the alternative exemplary UBM structure.

FIG. 8B illustrates a cross sectional view of the metal seed layer after the exposed metal is chemically etched and the photo resist is removed for the alternative exemplary UBM structure.

FIG. 9A illustrates a top view of the finished UBM structure after the patterned electroless nickel is on the metal seed layer structure for the alternative exemplary UBM structure.

FIG. 9B illustrates a cross sectional view of the finished UBM structure after the patterned electroless nickel is on the metal seed layer for the alternative exemplary UBM structure.

FIG. 10A illustrates a top view of the device where an alternative process for producing the device is utilized, and a patterned photo resist layer placed on the metal seed layer is shown.

FIG. 10B illustrates a cross sectional view of the device where an alternative process for producing the device is utilized, and a patterned photo resist layer placed on the metal seed layer is shown.

FIG. 11A illustrates a top view of the device where the alternative process for producing the device is utilized, and the device is shown after the electroless nickel has been deposited on the seed layer with the photo resist layer.

FIG. 11B illustrates a cross sectional view of the device where the alternative process for producing the device is utilized, and the device is shown after the electroless nickel has been deposited on the seed layer with the photo resist layer.

FIG. 12A illustrates a top view of the device where the alternative process for producing the device is utilized, and after the photo resist has been removed from the electroless nickel layer on the seed layer.

FIG. 12B illustrates a cross sectional view of the device where the alternative process for producing the device is utilized, and after the photo resist has been removed from the electroless nickel layer on the seed layer.

FIG. 13A illustrates a top view of the finished UBM structure after the electroless nickel process, and after chemical etching of the exposed seed metal.

FIG. 13B illustrates a cross sectional view of the finished UBM structure after the electroless nickel process, and after chemical etching of the exposed seed metal.

FIG. 14 illustrates a graph depicting the drop test results of various types of UBM where the implementation of electroless nickel shows an increased number of drops before failure.

FIG. 15 illustrates a graph depicting the drop test results of various types of UBM where the implementation of electroless nickel shows a decreased failure rate after 500 drops.

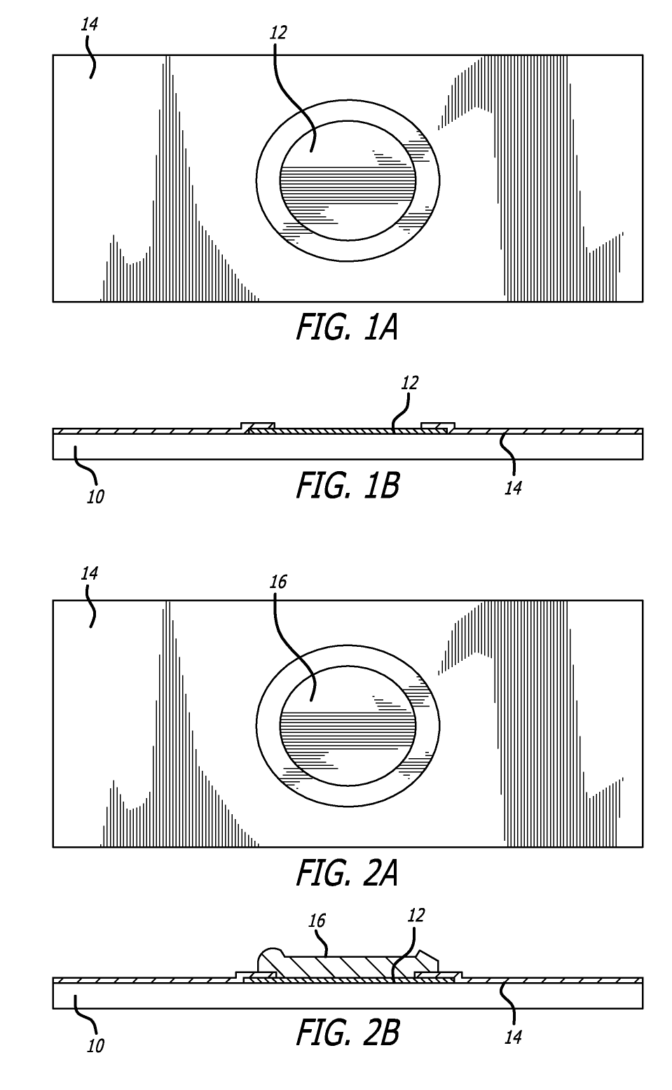

### DETAILED DESCRIPTION

An under bump metallization (UBM) structure having a film metal layer to serve as a seed layer for the deposition of electroless nickel or electroless nickel alloy is disclosed. The seed layer may be any material or metal that adheres to electroless nickel. The use of a metal seed layer in conjunction with an electroless nickel layer creates an under bump metallization providing improved thermo-mechanical robustness and drop test performance. This improved mechanical performance for wafer level packaging applications is achieved through the inherently low brittleness of the UBM structure, improved adhesion of the electroless nickel to otherwise non-conductive surfaces, and optimized design for the electroless nickel UBM deposition.

Utilization of the seed layer allows for the use of electroless nickel as an UBM on devices that do not have the proper final metal alloy as an electrical contact. For example, the disclosed UBM having a thin metal seed layer allows for the use of the same electroless nickel deposition process on various metals used as electrical contacts in electronic devices, such as pure aluminum, copper, and gold. In addition, it provides for excellent adhesion of electroless nickel to non-conductive surfaces such as oxide, nitride, and polymer layers. Further, it stabilizes the electroless nickel deposition process by removing a primary source of variation from the process. For example, if used as an unpatterned blanket layer, the UBM eliminates variation in plating on various electrical contacts of the electronic device that is otherwise caused by the interaction with active devices contained within the electronic device.

In the case of electronic devices, this metal seed layer is deposited over the passivation contact opening to seal the opening and create an optimized surface for the deposition of electroless nickel. The seed layer can also be deposited and patterned in areas outside of the passivation contact opening to allow for patterned deposition of the electroless nickel.

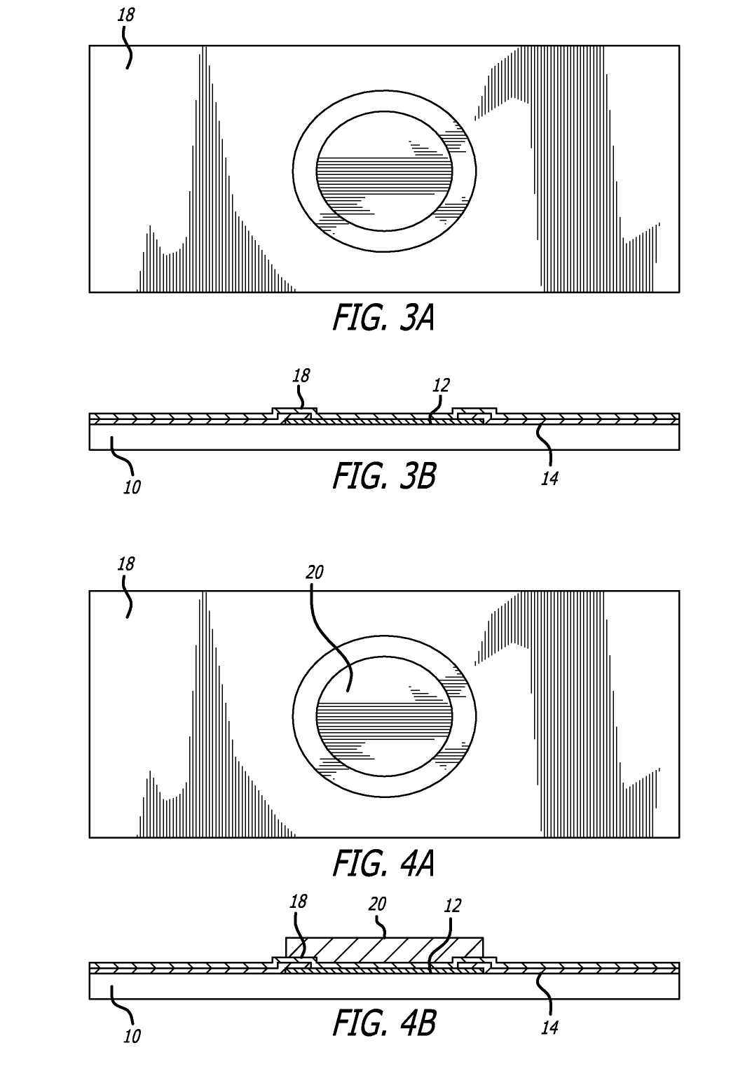

To prepare this structure, two differing methods may be performed. FIGS. 3 through 6 illustrate a first embodiment for forming the improved UBM structures. First, as illustrated in FIGS. 3A and 3B, at least one metal seed layer 18 is deposited through the use of sputter or plating deposition, and optimized for the intended electroless nickel deposition. The metal seed layer 18 covers the passivation layer 14 and the final metal layer 12. In exemplary embodiments, the deposited metal seed layer 18 can consist of an aluminum copper alloy, a layered structure such as titanium, other sputtered materials followed by an aluminum-copper alloy, or other suitable alloys selected for deposition of electroless nickel.

The deposition of the electroless nickel onto the metal seed layer 18 enables the structure to better seal the passivation opening and the electrical contact of the electronic device. This creates a stronger electrical connection, thereby improving the performance of the flip chip or wafer.

Additionally, the thin metal seed layer 18 allows electroless nickel UBM 16 to be deposited on final metal and fragile structures that are otherwise too thin for a reliable connection to be made. This enables a more versatile UBM to be utilized with a greater number of materials.

In other embodiments, the metal seed layer is deposited before the electroless nickel deposition to suppress device-dependent variations in electroless nickel thickness.

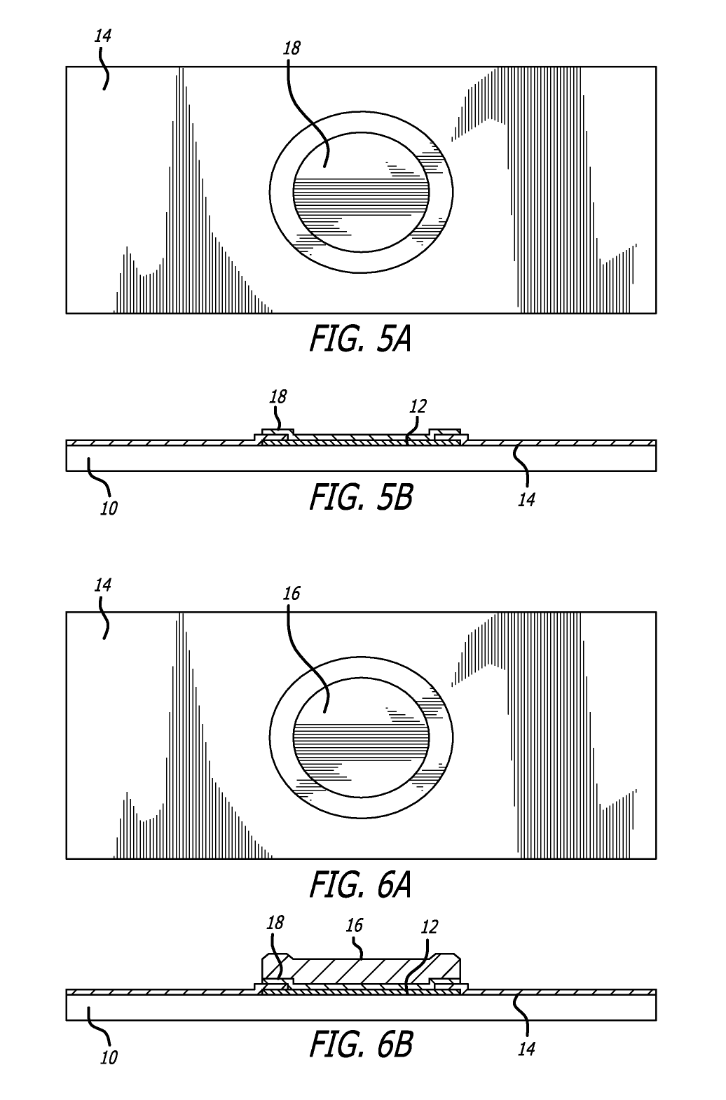

Then, as depicted in FIGS. 4A and 4B, a photo resist pattern is placed on the metal layer 18. The deposited layer with photo resist 20 covers the intended area of electroless nickel deposition. Chemical etchants are then utilized to remove the unwanted metal in areas that are not protected by photo resist 20. The photo resist 20 is then removed with a suitable, conventional photo resist strip process. This leaves a patterned metal seed layer 18 covering the final metal layer 12 in the passivation opening as shown in FIGS. 5A and 5B. Finally, the electroless nickel deposition process is performed, thereby creating an UBM 16 having good adherence to the final metal layer 12, and providing a strong electrical connection in the device as illustrated in FIGS. 6A and 6B.

In exemplary embodiments, titanium or other sputtered material may be used for adhesion having a thickness of about 200 to 5,000 Angstroms. In other exemplary embodiments, aluminum copper alloy may be used as a seed metal for electroless Ni having a thickness of about 2,000 to 20,000 Angstroms. In other exemplary embodiments, the electroless nickel may have a thickness of 0.5 microns to 50 microns. Typically the patterned seed layer will be round in shape, and larger than the passivation opening. However, the specific diameter will vary based on the desired bump height.

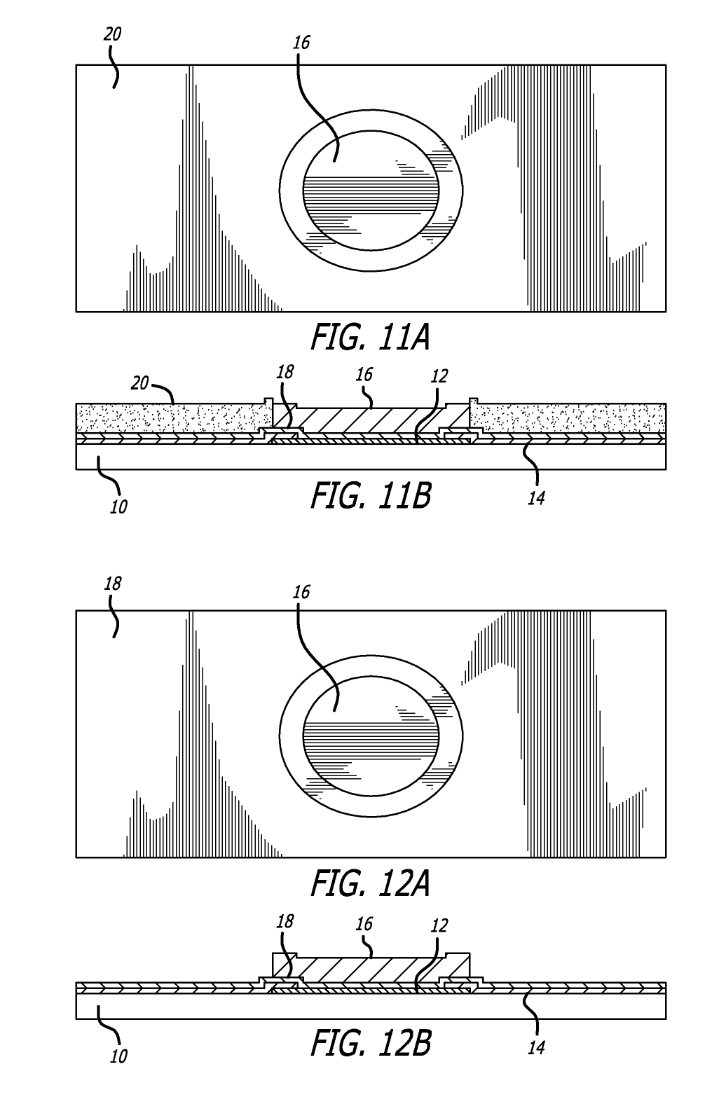

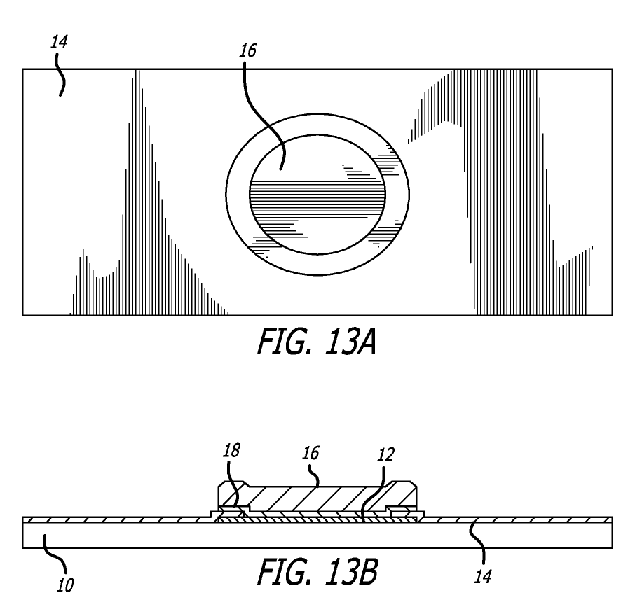

In an alternative embodiment, illustrated by FIGS. 10 through 13, sputter deposition of at least one metal seed layer 18 on the passivation layer 14 is completed to optimize for the intended electroless nickel deposition. As depicted in FIGS. 10A and 10B, a photo resist pattern is deposited with the photo resist 20 covering the area that is to be protected from electroless nickel deposition.

Then, the electroless nickel deposition process is completed with the photo resist 20 in place. The photo resist 20 is then subsequently removed with a suitable photo resist strip process. Finally, chemical etchants are utilized to remove the unwanted seed metal using the deposited electroless nickel as a protective masking layer. This provides a UBM 16 having good adherence to the final metal layer 12 and providing a strong electrical connection similar to the device illustrated in FIGS. 6A and 6B.

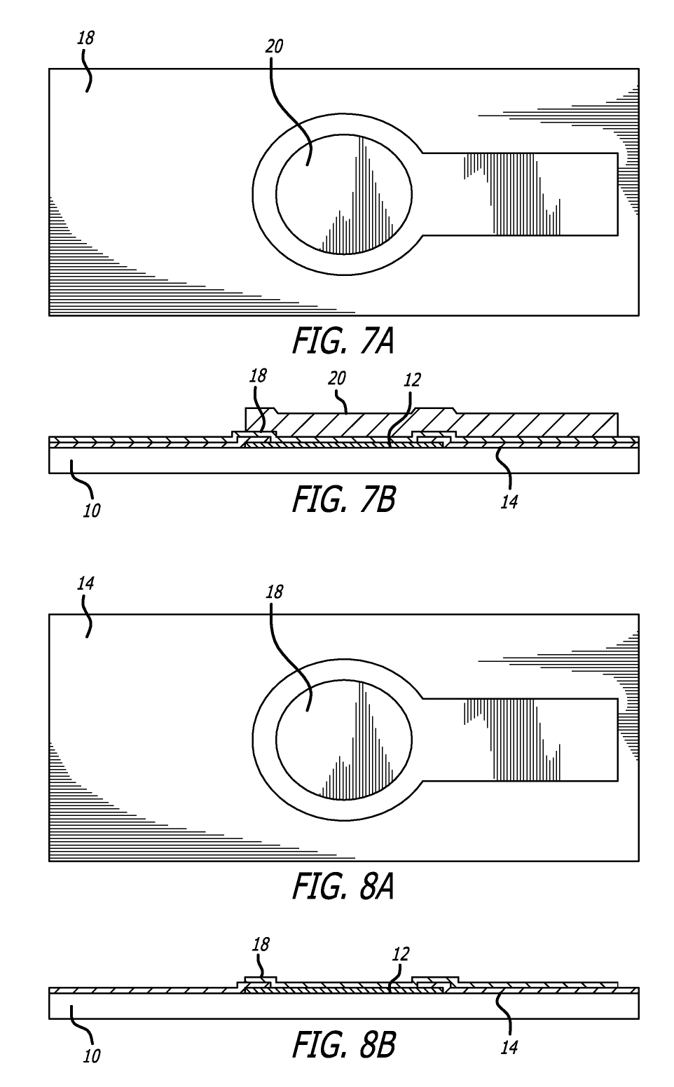

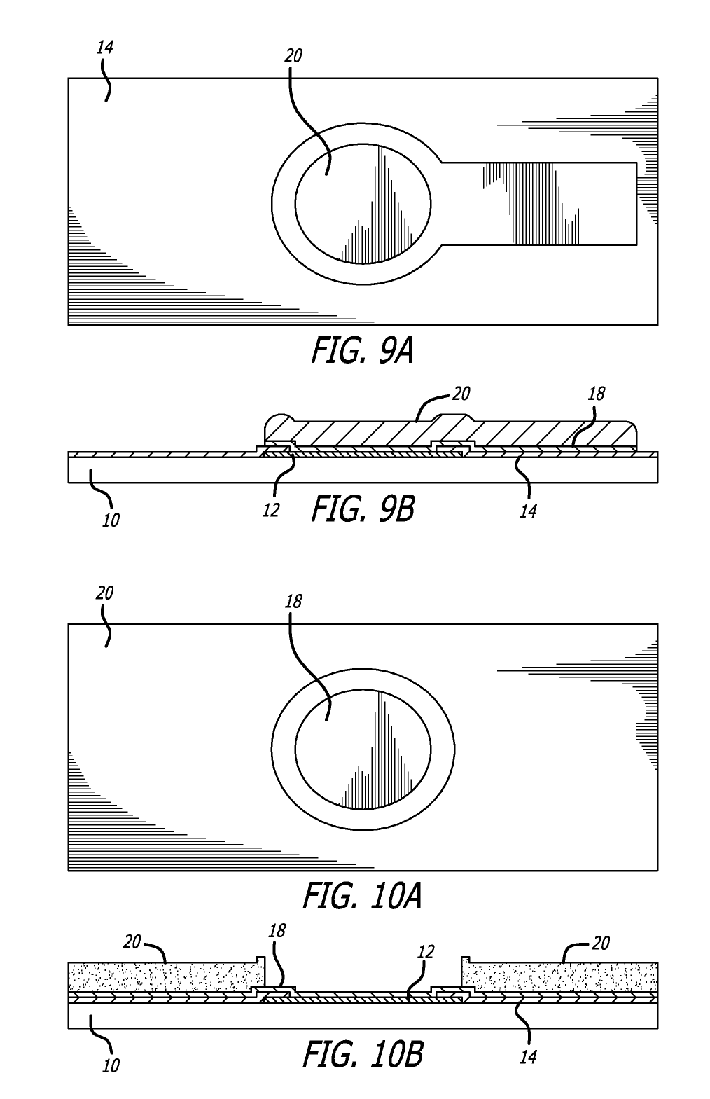

FIGS. 7 through 9 show a process that allows for the design of the electroless nickel to be optimized into underlying structures for improved mechanical performance in impact and drop tests. A metal seed layer 18 is produced on the passivation layer 14. Then, a patterned photo resist structure 20 is created on the metal seed layer. In this embodiment, patterned photo resist layer 20 includes a portion overlapping the passivation opening and a portion overlapping the passivation layer 14. Then, the metal seed layer 18 and the subsequent electroless nickel UBM overlap not only the final metal 12 in the passivation opening 15, but also a portion of the passivation layer 14. By allowing the UBM to be placed on a portion of the passivation layer 14, the device becomes more thermo-mechanically robust.

Although described herein as employing circular geometries or the exemplary geometry illustrated and discussed in reference to FIGS. 6 through 9, alternative geometries may be substituted for the UBM and seed layer without departing from the spirit and scope of the disclosure. By way of an example embodiment, one or more of the structures may be defined by utilizing a square geometry. Additionally, examples of the geometries that may be employed can be found in U.S. Provisional Patent Application No. 60/913,337 (entitled Bump Interconnect for Improved Mechanical and Thermo-Mechanical Performance by ALVARADO et al.), which is hereby incorporated by reference for at least its teachings regarding packaging applications, structures, and fabrication methods.

In addition, by allowing the process to create other geometric structures for the UBM, an electroless nickel UBM may be properly sized for the intended bump application independent of the size of the passivation opening or electrical contact of the electronic device. Alternatively, other structures are also possible. For example, dummy bumps or other necessary structures may be constructed. Furthermore, this process allows for the creation of a uniformly sized electroless nickel pattern on electronic devices with a variety of passivation contact opening sizes.

The Joint Electron Device Engineering Council (JEDEC) JESD22-B1 11 standard provides a method of evaluating a flip chip or wafer level chip's ability to withstand the mechanical shock that a semiconductor device would experience if it was in a portable device that was dropped. This is important as these devices are utilized in mobile phones and personal digital assistants (PDAs). These devices may be dropped many times by consumers who expect these devices to continue to work. JEDEC requires that these devices must withstand at least 30 drops without failure.

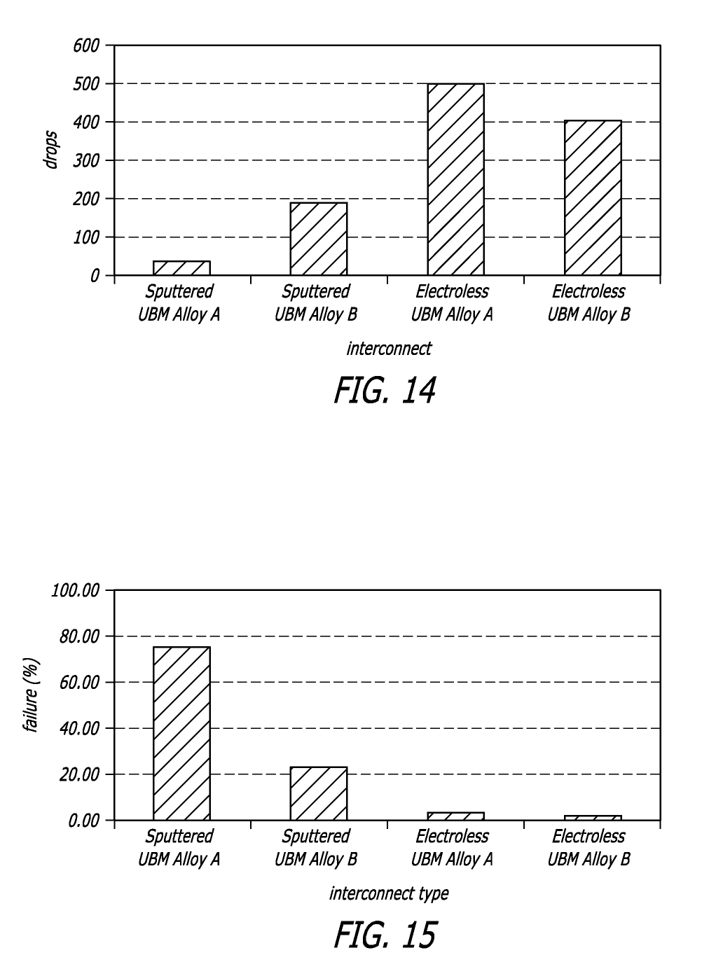

FIGS. 14 and 15 illustrate the testing results from exemplary UBM structures made in accordance with the above description. These structures formed from electroless nickel sustained at least 400 drops before the first failure. Additionally, the electroless nickel devices exhibited a failure rate of less than 5% failure after 500 drops. The conventional devices having only a sputtered UBM failed more quickly, having a first failure at under 200 drops in one example, and in another exemplary example, having a first failure at just over the JEDEC specification of 30 drops. The conventional sputtered devices also had a much higher percentage of failure, exceeding over 20% failure after 500 drops than the electroless nickel UBM. The presently disclosed structure provides the increased thermo-mechanical stability along with the other benefits of electrical stability of the sputtered metal UBM devices. In addition, the implementation of the geometries described herein of differently-shaped device structures enhances the thermo-mechanical stability as well.

While the specific exemplary structures and methods have been described in terms of what are presently considered to be the most practical and preferred embodiments, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

1. An under bump metallization (UBM) structure, comprising:
a semiconductor substrate, having a passivation layer formed thereover, and a plurality of final metal layers exposed through openings in said passivation layer;
a metal seed layer formed over and extending beyond each of the passivation openings exposing the final metal layers;
the metal seed layer formed over non-conductive materials such as nitride, oxide, or various polymers used in the final passivation layer of electronic devices;
a metallization layer formed from electroless deposition over the metal seed layer.

2. The UBM structure of claim 1 wherein the metal seed layer is deposited before electroless nickel deposition to suppress device-dependent variations in electroless nickel thickness.

3. The UBM structure of claim 1 wherein the metal seed layer is deposited to seal the passivation opening and electrical contact of the electronic device prior to the deposition of electroless nickel UBM.

4. The UBM structure of claim 1 wherein the metal seed layer is deposited prior to electroless nickel UBM to be properly sized for the intended bump application and optimized for thermo-mechanical performance independent of the size and shape of the passivation opening or electrical contact of the electronic device.

5. The UBM structure of claim 1 wherein a metal seed layer is deposited to enable the use of electroless nickel on very thin final metals and fragile structures on the device wafer.

6. An under bump metallization (UBM) structure, comprising:
a semiconductor substrate;
at least one final metal layer,
wherein the at least one final metal layer is formed over at least a portion of the semiconductor substrate;
a passivation layer,
wherein the passivation layer is formed over at least a portion of the semiconductor substrate,
wherein the passivation layer includes a plurality of openings,
wherein the passivation layer is formed of a non-conductive material,
wherein the at least one final metal layer is exposed through the plurality of openings;
a metal seed layer,
wherein the metal seed layer is formed over the passivation layer and covers the plurality of openings;
a metallization layer,
wherein the metallization layer is formed over the metal seed layer,
wherein the metallization layer is formed from electroless deposition.

7. The UBM structure of claim 6 wherein the metal seed layer is deposited before electroless nickel deposition to suppress device dependent variations in electroless nickel thickness.

8. The UBM structure of claim 6 wherein the metal seed layer is deposited to seal the plurality of openings in the passivation layer and electrical contact of the electronic device prior to the deposition of electroless nickel UBM.

9. The UBM structure of claim 6 wherein the metal seed layer is deposited prior to electroless nickel UBM to be properly sized for the intended bump application and optimized for thermo-mechanical performance independent of the size and shape of the passivation opening or electrical contact of the electronic device.

10. The UBM structure of claim 6 wherein a metal seed layer is deposited to enable the use of electroless nickel on very thin final metals and fragile structures on the device wafer.
